(19) United States
(12) Patent Application Publication
(10) Pub. No.: US 2014/0342517 A1
(43) Pub. Date: Nov. 20, 2014

(54) METHOD FOR FABRICATING TRENCH TYPE POWER SEMICONDUCTOR DEVICE

(71) Applicant: Anpec Electronics Corporation, Hsin-Chu (TW)

(72) Inventors: Yung-Fa Lin, Hsinchu City (TW); Chia-Hao Chang, Hsinchu City (TW)

(21) Appl. No.: 13/923,325

(22) Filed: Jun. 20, 2013

(30) Foreign Application Priority Data
May 14, 2013 (TW) 102117059

(51) Int. Cl. H01L 29/66

(52) U.S. Cl. CPC H01L 29/66734
USPC 438/270

(57) ABSTRACT

A method of forming a trench type semiconductor power device is disclosed. An epitaxial layer is formed on a substrate. A gate trench is formed in the epitaxial layer. A gate oxide layer and a trench gate are formed in the gate trench. A source region is then formed in the epitaxial layer. A dielectric layer is then deposited in a blanket manner. A contact hole is then formed in the dielectric layer and the epitaxial layer. A base ion implantation is then carried out to form at least one doping region in the epitaxial layer through the contact hole. A contact hole implantation process is then performed to form a contact doping region at the bottom of the contact hole.

### BACKGROUND OF THE INVENTION

1. Field of the Invention

The present invention relates generally to the field of semiconductor technology. More particularly, the present invention relates to a method for fabricating a trench type power semiconductor device with super junction structure.

2. Description of the Prior Art

As known in the art, the rise of on-resistance of traditional planar power DMOS devices (DMOS) is contributed from the channel region, the accumulation layer and junction field effect transistor (JFET).

In order to reduce the resistance of the above-mentioned area, trench type power devices (UMOS) are proposed. Since JFET region does not exist in a UMOS, the cell size can be reduced and the channel density is increased, thereby resulting in a lower on-resistance.

The present invention is concerned with a method for fabricating a trench type power semiconductor device with super junction structure, which is capable of reducing on-resistance, eliminating damage to the gate oxide layer during ion implantation, improving quality of the gate oxide layer, and reducing subthreshold current (Isub).

### SUMMARY OF THE INVENTION

According to one embodiment, a method for fabricating a trench type power semiconductor device with super junction structure is disclosed. A semiconductor substrate having a first conductivity type is provided. An epitaxial layer is then formed on the semiconductor substrate. At least one gate trench is formed in the epitaxial layer. A gate oxide layer is formed in the gate trench. A gate is formed in the gate trench. An ion implantation process is then performed to form a source doping region in the epitaxial layer. A dielectric layer is deposited to cover the gate and the gate oxide layer in a blanket manner. The dielectric layer and the epitaxial layer are etched to form contact hole. A base ion-implantation process is then performed to form at least one doping region in the epitaxial layer through the contact hole. A contact hole ion-implantation process is then performed to form a contact doping region at a bottom of the contact hole.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1˜9 are schematic, cross-sectional diagrams illustrating an exemplary method for fabricating a trench type power semiconductor device with super junction structure in accordance with one embodiment of this invention.

### DETAILED DESCRIPTION

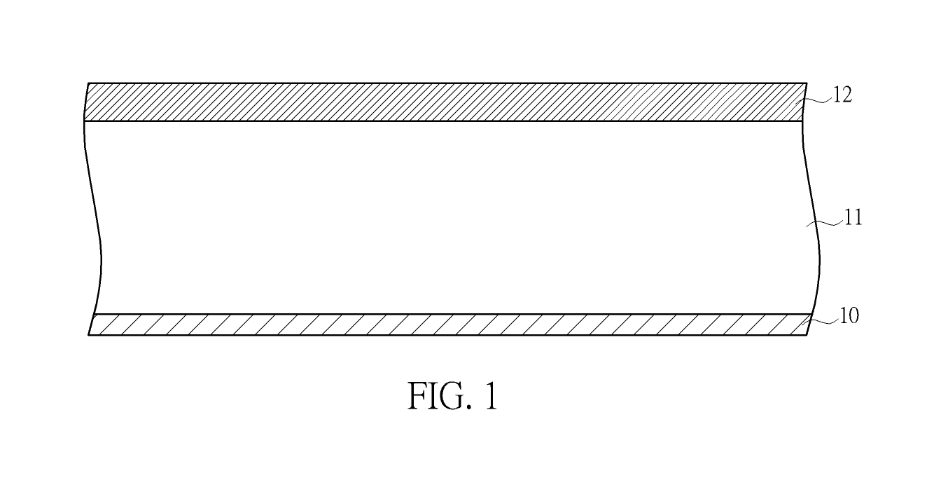

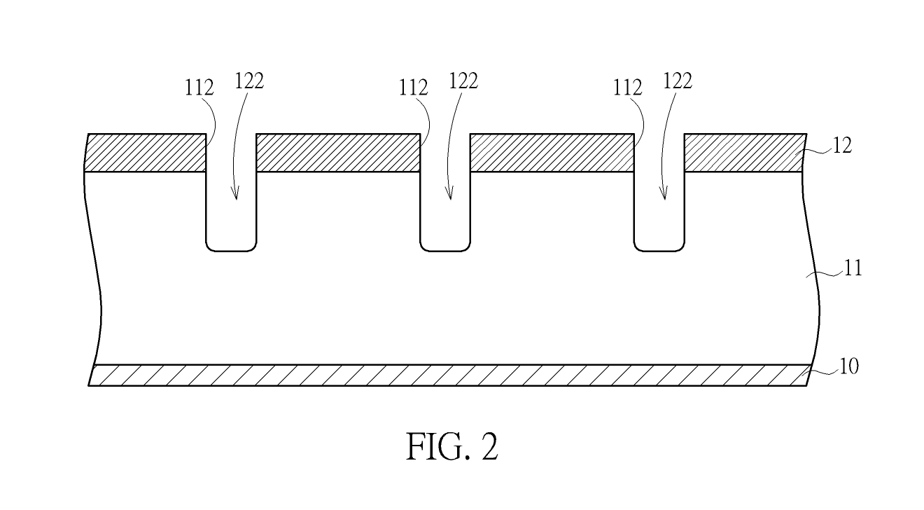

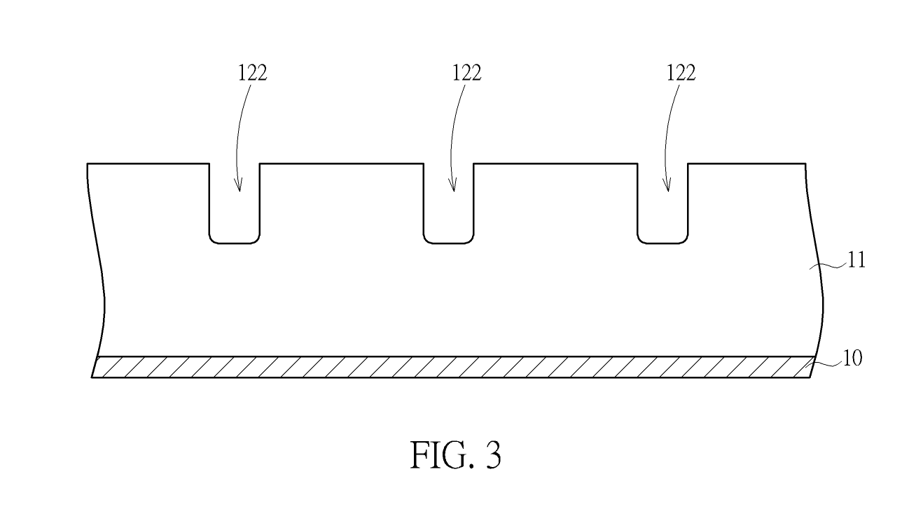

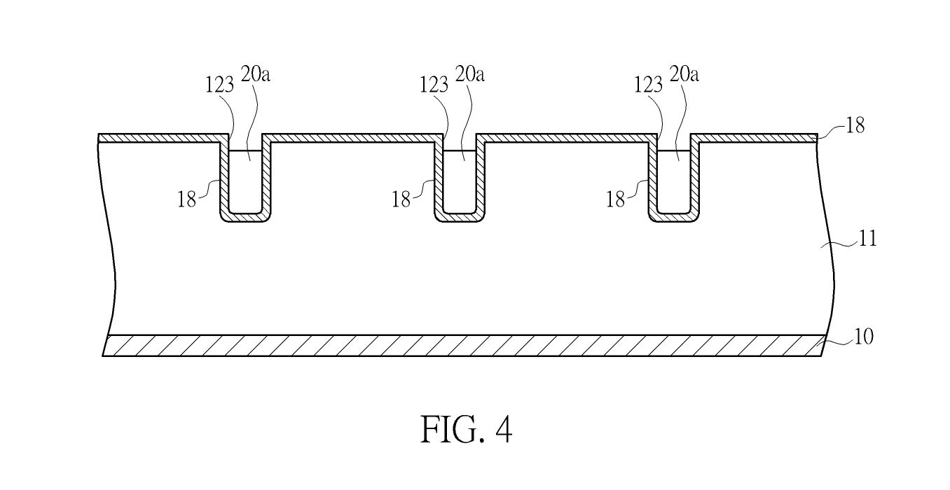

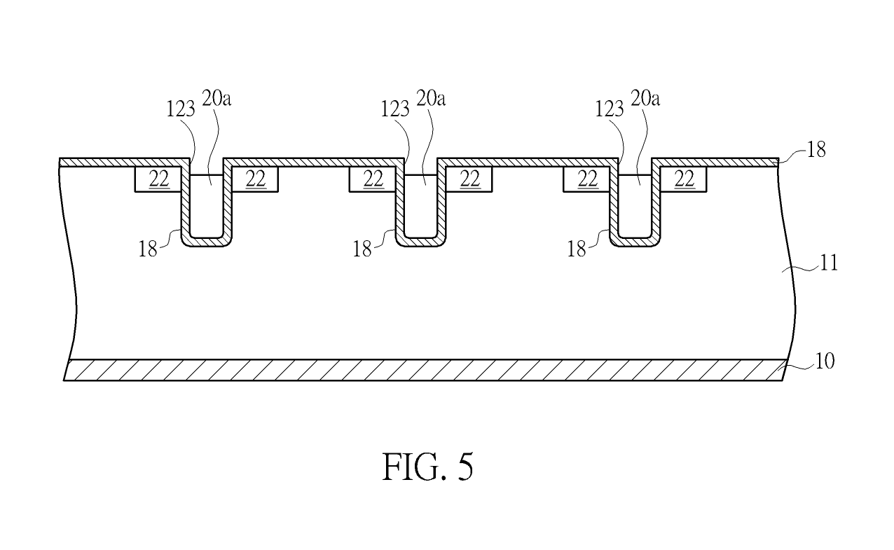

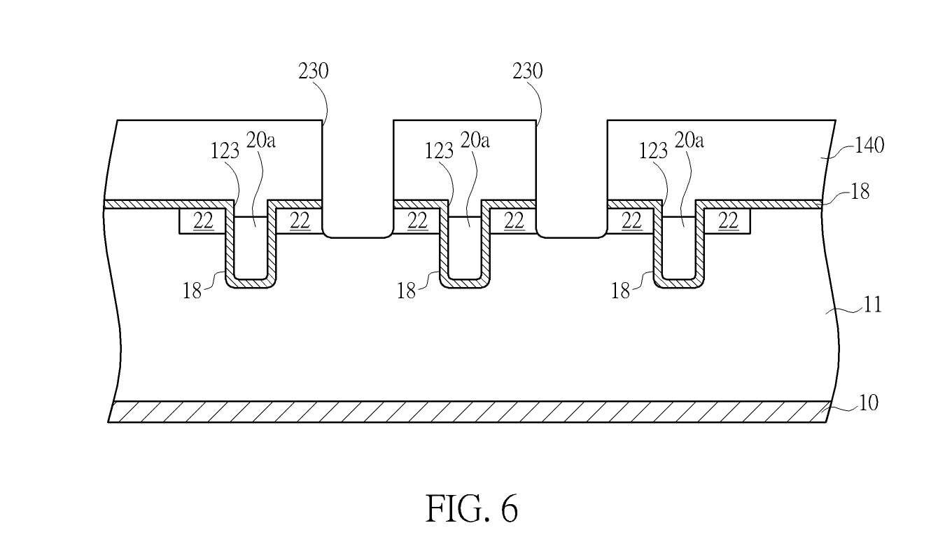

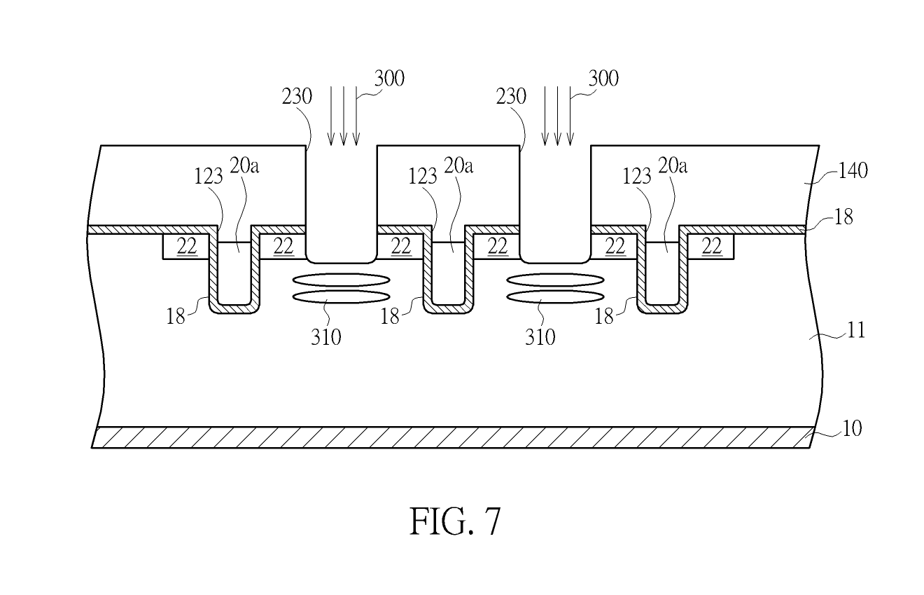

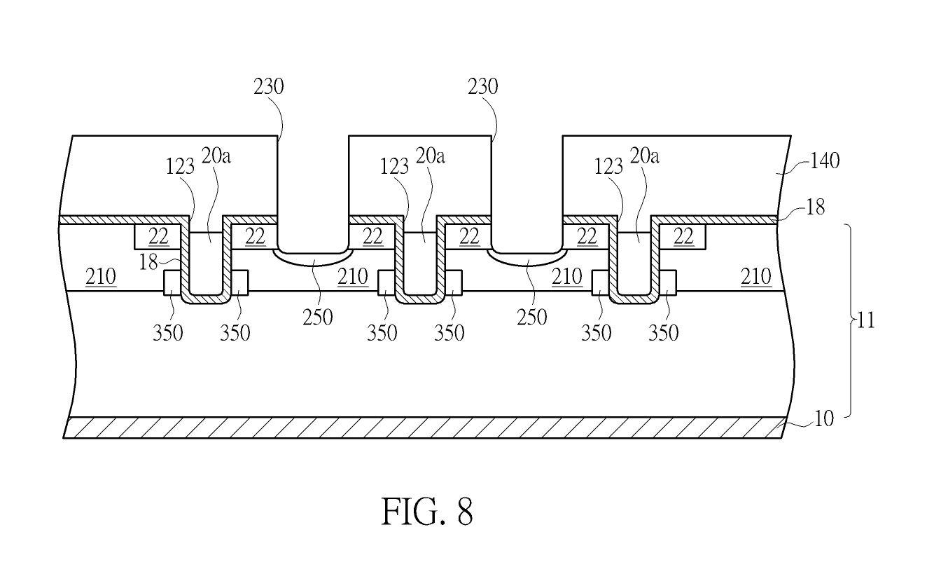

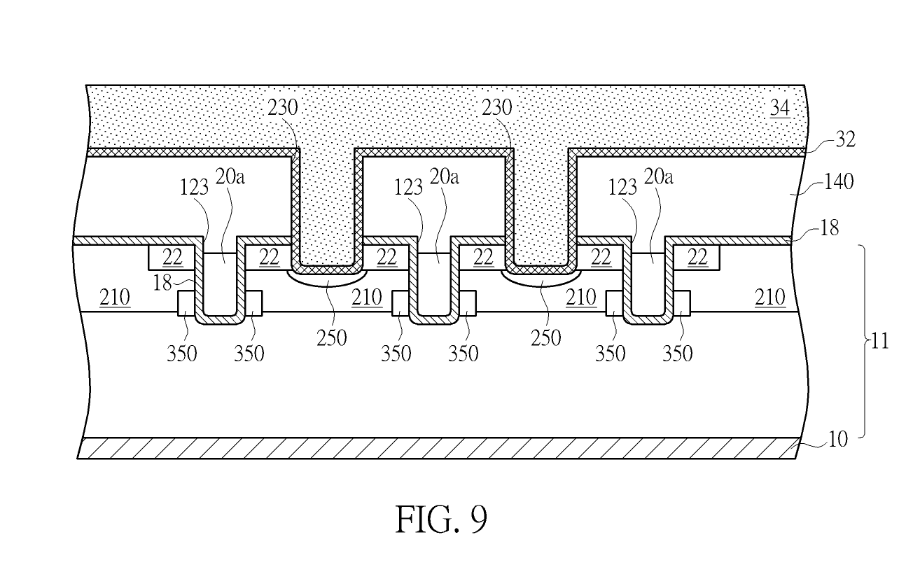

FIGS. 1˜9 are schematic, cross-sectional diagrams illustrating an exemplary method for fabricating a trench type power semiconductor device with super junction structure in accordance with one embodiment of this invention. As shown in FIG. 1, a semiconductor substrate 10 such as an N type doped silicon substrate is provided. The semiconductor substrate 10 may function as a drain of the transistor device. An epitaxial layer 11 such as an N type epitaxial silicon layer is formed on the semiconductor substrate 10 by using an epiaxial growth process. A hard mask 12 is then formed on the epitaxial layer 11. For example, the hard mask 12 may be a silicon oxide layer or a silicon nitride layer.

Subsequently, as shown in FIG. 2, openings 112 are formed in the hard mask layer 12 by using lithographic and etching processes. The openings 112 may be defined by a photoresist layer (not shown). After removing the photoresist layer, a dry etching process is carried out to etch the epitaxial layer 11 through the openings 112 in the hard mask layer 12 to a predetermined depth, thereby forming gate trenches 122.

As shown in FIG. 3, an oxidation process may be performed to form a sacrificial oxide layer (not shown) on the surfaces of the gate trenches 122. The hard mask layer 12 and the sacrificial oxide layer are then removed. The top surface of the epitaxial layer 11 is exposed and the gate trenches 122 are remained.

As shown in FIG. 4, a thermal oxidation process is carried out to form a gate oxide layer 18 on the top surface of the epitaxial layer 11 and the interior surface of each of the gate trenches 122. A chemical vapor deposition (CVD) process is then performed to deposit a polysilicon layer (not explicitly shown) in a blanket manner. The polysilicon layer fills into the gate trenches 122. An etching process is then performed to remove excess polysilicon layer outside the gate trenches 122 and the remaining polysilicon layer within each of the gate trenches 122 constitutes trench gate 20a. At this point, a recess 123 may be formed directly above the trench gate 20a. It is understood that in addition to polysilicon, the gate trenches 122 may be composed of other materials such as metals or metal silicides.

As shown in FIG. 5, an ion implantation process is then performed to form source doping regions 22 in the epitaxial layer 11 on both sides of each of the gate trenches 122. The source doping regions 22 may be N+ source doping regions. Subsequently, a thermal drive-in process may be performed to diffuse or activate the dopants. It is understood that a lithographic process may be carried out to define the source regions to be implanted by using a photoresist pattern prior to the ion implantation process.

As shown in FIG. 6, a CVD process is performed to deposit a dielectric layer 140 in a blanket manner. The dielectric layer 140 covers the trenches gates 20a and the gate oxide layer 18 outside the gate trenches 122. A lithographic process is then performed to form a photoresist pattern (not shown) on the dielectric layer 140 to define the position and pattern of contact holes. Then, using the photoresist pattern as an etching hard mask, the dielectric layer 140 and the epitaxial layer 11 are etched to a predetermined depth thereby forming the contact holes 230. The photoresist pattern is then removed.

As shown in FIG. 7, a base ion-implantation process 300 is then performed to form at least one doping region 310 such as P type doping region into the epitaxial layer 11 through each of the contact holes 230. The aforesaid base ion-implantation process 300 may comprise single-time or multiple-time implant steps with a doping energy ranging between 40˜1000 KeV and a dosage ranging between 1E12˜1E14atoms/cm2.

As shown in FIG. 8, a thermal drive-in process at a temperature between 900˜1200° C. is then performed to diffuse or activate the dopants, thereby forming ion wells 210 between gate trenches 122. A contact hole ion-implantation process is then performed to form contact doping region 250 such as P+ doping region at the bottom of each of the contact holes 230. The contact hole ion-implantation process may have a doping energy ranging between 40˜120 KeV and a dosage ranging between 1E12˜1E14atoms/cm2. A tilt-angle ion-implantation process is then performed to implant P type dopants into the epitaxial layer 11 adjacent to the gate trenches 122, thereby forming sidewall doping regions 350. Subsequently, a rapid thermal annealing process may be performed.

As shown in FIG. 9, a barrier layer 32 and a metal layer 34 are deposited in a blanket manner. The contact holes 230 may be filled with the metal layer 34.

The present invention may be characterized in that the base or P well 210 is formed after the formation of the contact holes 230. By doing this, when performing the base ion-implantation process 300, the gate oxide layer 18 in the gate trenches 122 can be protected by the dielectric layer 140 from implant induced damages, thereby improving quality of the gate oxide layer, and reducing subthreshold current (Isub).

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a trench type power semiconductor device with super junction structure, comprising:
providing a semiconductor substrate having a first conductivity type;
forming an epitaxial layer on the semiconductor substrate;
forming at least one gate trench in the epitaxial layer;
forming a gate oxide layer in the gate trench;
forming a gate in the gate trench;
performing an ion implantation process to form a source doping region in the epitaxial layer;
blanket depositing a dielectric layer to cover the gate and the gate oxide layer;
etching the dielectric layer and the epitaxial layer to form contact hole;
performing a base ion-implantation process to form at least one doping region in the epitaxial layer through the contact hole; and
performing a contact hole ion-implantation process to form a contact doping region at a bottom of the contact hole.

2. The method for fabricating a trench type power semiconductor device with super junction structure according to claim 1 wherein after forming the contact doping region, the method further comprises:
performing a tilt-angle ion-implantation process to implant dopants into the epitaxial layer adjacent to the gate trench thereby forming a sidewall doping region; and
performing a rapid thermal annealing process.

3. The method for fabricating a trench type power semiconductor device with super junction structure according to claim 1 wherein after performing the base ion-implantation process, the method further comprises:
performing a thermal drive-in process to diffuse the dopants of the doping region, thereby forming an ion well.

4. The method for fabricating a trench type power semiconductor device with super junction structure according to claim 3 wherein the epitaxial layer has the first conductivity type, the ion well has a second conductivity type, and the source doping region has the first conductivity type.

5. The method for fabricating a trench type power semiconductor device with super junction structure according to claim 4 wherein the first conductivity type is N type and the second conductivity type is P type.

6. The method for fabricating a trench type power semiconductor device with super junction structure according to claim 4 wherein the thermal drive-in process is carried out at a temperature ranging between 900˜1200° C.

7. The method for fabricating a trench type power semiconductor device with super junction structure according to claim 1 wherein the base ion-implantation process comprises single-time or multiple-time implant steps.

8. The method for fabricating a trench type power semiconductor device with super junction structure according to claim 1 wherein the base ion-implantation process is performed with a doping energy ranging between 40˜1000 KeV and a dosage ranging between 1E12˜E14atoms/cm2.

9. The method for fabricating a trench type power semiconductor device with super junction structure according to claim 1 wherein the contact hole ion-implantation process is carried out with a doping energy ranging between 40˜120KeV and a dosage ranging between 1E12˜1E14atoms/cm2.

10. The method for fabricating a trench type power semiconductor device with super junction structure according to claim 1 wherein the source doping region is adjacent to the gate trench.
